(19) United States
(12) Patent Application Publication
(10) Pub. No.: US 2009/0152402 A1
(43) Pub. Date: Jun. 18, 2009

(54) Satellite, method and a fleet of satellites for observing a celestial body

(75) Inventor: Didier Massonnet, Saint-Orens (FR)

Correspondence Address: YOUNG & THOMPSON, 209 Madison Street, Suite 500, ALEXANDRIA, VA, 22314, US

(73) Assignee: CENTRE NATIONAL D'ETUDES SPATIALES (C.N.E.S.), PARIS CEDEX 1 (FR)

(21) Appl. No.: 11/587,007

(22) PCT Filed: Apr. 15, 2005
(86) PCT No.: PCT/FR2005/000911

§ 371 Date: Dec. 18, 2006

(30) Foreign Application Priority Data
Apr. 23, 2004 (FR) 0404327

(51) Int. Cl. B64G 1/10; B64G 1/64; B64G 1/38; H01L 31/042; H01L 31/052

(52) U.S. Cl. 244/158.2; 244/172.6; 244/170; 244/158.4; 244/158.5; 136/244; 136/246

(57) ABSTRACT

The invention concerns an observation satellite (1) which is intended to be placed in orbit around a celestial body (2), and which comprises a reflecting device (5), a receiving device (6), a linking mechanical system (19), the whole forming a capture system (3) which is suitable to be able to orient the capture system (3) by gravity gradient in an aiming position in which the electromagnetic radiation corresponding to the information to be captured is received.

The invention extends to an observation method and a fleet of such satellites (1).

The invention concerns an observation satellite which is intended to be placed in orbit around a celestial body. It extends to a method of observing a celestial body using at least one satellite according to the invention, in particular using a fleet of satellites according to the invention.

In particular, the invention applies to an observation in the infrared range, to an observation and in the visible range, to passive microwave radiometry, to altimetry and to radar imaging of the Earth or another celestial body.

Known satellites for observation in the visible range include an optical observation system and so-called active attitude control systems. The functional architecture of active attitude control systems is divided into two systems: sensors for angular velocity, angular displacement, etc., which make it possible to obtain relevant measurements of the attitude of the satellite according to three reference axes which are chosen for the satellite, and actuators which induce torques around the three axes of the satellite, making it possible to reorient it.

Additionally, the precision of the optical systems is closely linked to the correct positioning of the optical components among themselves and in relation to a frame of the satellite. Some on-board optical systems, e.g. those of the SPOT satellites, include so-called active optical components, which can be adjusted in space from the ground. It is thus possible to change the aiming orientation of the optical system in relation to the frame of the satellite. These systems are heavy, bulky and therefore extremely expensive. Often, therefore, when the application allows, systems with so-called passive optical components, i.e. those which are adjusted and fixed in relation to the frame on the ground, and the position of which cannot be adjusted in flight, are preferred to them.

The problem which is raised is thus that of the precision of the initial adjustment on the ground, and of keeping this adjustment in the phases of takeoff (during which the system must be able to tolerate strong accelerations, typically of 30 g or more, while allowing for vibration phenomena), and then in space in the absence of gravity. The solutions which have been developed to solve this problem involve very complex adjustment mechanisms to make it possible to reach the desired threshold of resolution, while keeping the system within a compact volume.

Known observation satellites are complex and therefore expensive to produce. They also weigh several hundred kilograms. Consequently, taking account of the financial stake and the weight of the load, putting them into orbit is a delicate, risky operation which makes it necessary to use specialized and therefore expensive launchers such as Ariane.

Typically, known satellite systems to observe the Earth use a small number of satellites, each of which carries out a considerable daily coverage of observation (e.g. the Spot 4 system (http://spot4.cnes.fr)). The breakdown of only one of these satellites therefore causes a significant loss of function of the system.

The invention is aimed at reducing these disadvantages by proposing an observation satellite which has simple architecture, is light, and of which the costs of production and putting it into orbit are low.

The invention is also aimed at proposing an observation satellite which is suitable for making it possible to launch, at low cost, a fleet consisting of numerous such satellites, in particular in a single launch or several launches.

To do this, the invention concerns an observation satellite which is intended to be placed in orbit around a celestial body, and which includes a suitable capture system to capture information which is received in the form of electromagnetic radiation, the capture system comprising:
a receiving device including a suitable detecting device to capture the said information,
a device to reflect the said received electromagnetic radiation, comprising at least one reflecting surface,
a linking mechanical system which moors the reflecting device and receiving device to each other,
   this capture system being suitable to be able to capture the said information when the receiving device and reflecting device are placed relative to each other in a functioning relative position in which the detecting device receives all or part of the said electromagnetic radiation which is reflected by the reflecting device, and captures the corresponding information, wherein the capture system is suitable, by its geometry and mass distribution, to orient itself of its own accord by gravity gradient according to an aiming orientation, in which when the receiving device and reflecting device are in a functioning relative position, the reflecting device is oriented toward the celestial body to be able to receive the electromagnetic radiation which originates in an area of the celestial body, called the aimed-at area, the capture system being capable of capturing information which is to be captured and is transmitted by this electromagnetic radiation.

Thus the capture system does not need specific means for positioning and orientation in relation to a frame of the satellite, nor a complex attitude control system. The reflecting device and receiving device have appropriate masses, and are placed in functioning positions which are sufficiently distant from each other to generate the necessary torque to drive the capture system toward an aiming orientation merely by the gravity gradient resulting from this capture system itself. Depending on the applications of the satellite according to the invention (meteorology, cartography, etc.), a tolerance is accepted in the aiming orientation taken by the satellite. Thus there is a range of possible aiming orientations which are close to an ideal aiming orientation, and make it possible to capture information on the aimed-at area with a required minimum fidelity threshold. The required minimum fidelity threshold depends on the application of the satellite according to the invention (meteorology, cartography, etc.).

The invention makes any supporting frame unnecessary. Thus, advantageously and according to the invention, the capture system is not based on a rigid structure acting as a frame of the satellite. It essentially consists of its payload that is the capture system. The observation satellite according to the invention is therefore light and has a simple architecture.

A satellite according to the invention can have a compact storage configuration in a launcher, significantly reducing the cost of putting it into orbit.

Advantageously and according to the invention, the linking mechanical system is suitable for placing the reflecting device and receiving device relative to each other in at least two distinct configurations, corresponding respectively to two states of the capture system:
one state called deployed, in which the reflecting device and receiving device are stabilized in the functioning relative position under the effect of the gravity gradient,
one state called folded, in which the receiving device and reflecting device are close to each other, and the capture system is more compact than in the deployed state, and therefore suitable for being loaded into a launcher and/or for storage.

Stabilization by gravity gradient necessitates that the capture system has, once deployed in space, a very axially elongated overall geometry, which is generally inappropriate for loading into a launcher. However, the linking mechanical system according to the invention makes it possible to fold the capture system into the folded state, making economical use of the space which is available in the launcher. Several ways of implementing such linking mechanical systems can be envisaged: telescopic system, system with retractable arm, linking system which is flexible under flexion, etc.

Advantageously and according to the invention, the linking mechanical system is of a type which is flexible and inelastic under flexion, and is suitable for stretching under the effect of the gravity gradient when the satellite is placed in orbit, until it reaches an equilibrium configuration in which the capture device is stabilized in the deployed state.

Thus once the capture system has been ejected from the launcher, it puts itself automatically into the deployed state under the effect of the gravity gradient, without the need for intervention and/or complex automatic mechanisms.

Advantageously and according to the invention, the linking mechanical system comprises at least three threadlike suspension lines which are rigid under traction and flexible and inelastic under flexion, and each having two extremities, of which the first extremity is fixed to the reflecting device and the second extremity is fixed to the receiving device, the said suspension lines being each fixed at distinct places of the reflecting device and receiving device, in such a way that:
the attitudes of the receiving device and reflecting device can stabilize relative to each other under the effect of the gravity gradient,
when the capture system is in the deployed state, the threadlike suspension lines do not intercept the electromagnetic radiation which comes from the reflecting surface(s) and advances toward the detecting device.

Advantageously and according to the invention, the threadlike suspension lines consist of one or more materials which are chosen so that the lengths of the threadlike suspension lines remain approximately constant despite the thermal fluctuations to which they may be subjected once the satellite is placed in orbit.

Advantageously and according to the invention, the threadlike suspension lines consist entirely or partly of one or more materials which are suitable for absorbing at least the electromagnetic radiation belonging to the spectral range to be observed, so that these suspension lines do not generate any interfering reflection on the detecting device. Advantageously and according to the invention, the threadlike suspension lines are chains.

Advantageously and according to the invention, the linking mechanical system comprises motorized means of adjusting the length of at least one of the threadlike suspension lines.

These motorized means of adjustment make it possible to carry out a fine adjustment of the position and/or orientation of the receiving device relative to the reflecting device, to place the reflecting device and receiving device in a functioning relative position. Advantageously and according to the invention, the motorized means of adjustment include at least one piezoelectric actuator.

Advantageously and according to the invention, the satellite comprises a plurality of masks which are jointly suitable, when the reflecting device and receiving device are in the functioning relative position, for masking the detecting device against the direct incidence of electromagnetic radiation belonging to the spectral range to be observed, and originating in sources which are external to the internal volume of the capture system, which is geometrically circumscribed by the mask(s), the linking mechanical system, the reflecting device and the receiving device.

Thus the electromagnetic radiation which the detecting device receives originates essentially in the aimed-at area.

Advantageously and according to the invention, the reflecting device includes at least one peripheral mask, called gutter, which is adapted to extend around the periphery of the reflecting surface(s). Advantageously and according to the invention, the receiving device includes at least one mask, called blinker, which extends as a whole toward the reflecting device when the reflecting device and receiving device are in the functioning relative position.

In particular, according to an advantageous embodiment of the invention, the blinker limits the field of vision of the detecting device to a solid angle surrounding the reflecting surface, whereas the gutter masks the whole of the portion outside the reflecting surface of the resulting field of vision.

Advantageously and according to the invention, the detecting device includes at least one detecting component comprising at least one detector which is chosen from charge transfer detectors, waveguides, microbolometers. Other detectors can be used.

Advantageously and according to the invention, in the satellite:
at least one reflecting surface is concave and has symmetry of revolution around an axis, called the axis of the reflecting device, and suitable for observing an area of the celestial body centered on the axis of the reflecting device,
the detecting component is at least approximately placed in the axis of the reflecting device when the reflecting device and receiving device are in the functioning relative position.

In particular, according to an advantageous embodiment of the invention, the reflecting surface of the reflecting device is in the form of a paraboloid of revolution. In this case, the functioning of the capture system is similar to that of a Newton telescope. In fact, the detecting component is at least approximately placed at the focal distance of the paraboloid, so that information can be captured. This position corresponds to a functioning relative position of the receiving device and reflecting device.

In particular, according to the preferred embodiment, the capture system is placed in an aiming position in which the axis of the reflecting device is perpendicular according to the vertical of the celestial body. The aimed-at area is then what the satellite is flying over.

Advantageously and according to the invention, the reflecting surface being in the form of a paraboloid of revolution, the ratio between the focal distance and the diameter of the reflecting surface is greater than 5.

Advantageously and according to the invention, the capture system includes at least one filter which blocks thermal infrared radiation, and is placed to protect the detecting component from thermal infrared radiation from the reflecting device.

Advantageously and according to the invention, the satellite includes an electrical power supply with photovoltaic cells. Advantageously and according to the invention, photovoltaic cells are arranged on at least one surface of the reflecting device, opposite the reflecting surface(s).

Advantageously and according to the invention, the satellite includes at least one flexible conducting power supply cord of a length greater than that of the linking mechanical system in the deployed state, and electrically connecting the photovoltaic cells which are arranged on the reflecting device to the receiving device.

In an advantageous embodiment of the invention, the observation satellite has no battery or storage battery. The capture system is therefore active only when the photoelectric cells are sufficiently exposed to electromagnetic radiation from a light source such as the Sun.

Advantageously and according to the invention, in the satellite:
the receiving device includes a bracket on which the detecting device is mounted so that it rotates around an axis, called the detection axis,
the detecting device includes a motorized device to orient the detecting device around the detection axis.

In particular, according to the preferred embodiment, the motorized orientation device is suitable to be able to adjust the angular position of the detecting component around the detection axis. When the capture system is in an aiming orientation, this makes it possible to reposition the detecting component in an optimum angular position for capture in relation to the trajectory of the satellite when it leaves this position.

Advantageously and according to the invention, the receiving device includes a device for electromagnetic and/or mechanical suspension of the detecting device relative to the bracket of the receiving device, with negligible friction.

Advantageously and according to the invention, the capture system includes a device, called the damping or amplifying device, to make it possible to damp or amplify the pitching or rolling oscillations of the satellite when the reflecting device and receiving device are in the functioning relative position.

Advantageously and according to the invention, the damping and amplifying device includes a suitable motor to lift or lower at least one mass along the detection axis.

Advantageously and according to the invention, the satellite includes a suitable telemetry device to transmit captured information to a reception station at a distance from the satellite.

Advantageously and according to the invention, the capture device includes a device to fix the receiving device temporarily within a blind area of the reflecting surface, making it possible to keep the capture system in the folded state.

Advantageously and according to the invention, the capture system includes suitable means to make it pivot around a transverse axis of the capture system when the reflecting device and receiving device are in the functioning relative position. The capture system can thus be tipped into an aiming orientation when it has stabilized by gravity gradient in a head to tail orientation relative to the aiming orientation.

Advantageously and according to the invention, the reflecting device is adapted so that the reflecting surface reaches a functional geometric equilibrium in less than a semi-period of revolution around the celestial body when the reflecting device is subjected to thermal stress by passing from a segment of orbit in which a source of thermal radiation is eclipsed to a segment of orbit which is exposed to the said source.

Advantageously and according to the invention, the mass of the satellite is less than 10 kilograms.

The invention extends to a method of observing a celestial body, in which:
at least one satellite according to the invention is placed in orbit around the celestial body,
each satellite 1 is allowed to orient itself by gravity gradient.

Advantageously and according to the invention, a fleet of several satellites is placed in at least one orbit.

According to an advantageous embodiment of the invention, the fleet of satellites consists of a large number of satellites, of the order of several hundred, e.g. 200 satellites. Thus the breakdown of one satellite causes only a slight loss of the capacity of the fleet to observe. The invention thus makes it possible to reduce the risks of the investment in utilization of a fleet of satellites according to the invention.

Advantageously and according to the invention, each satellite is placed in a non-geostationary orbit, and a suitable, sufficient number of satellites is used to make it possible statistically to capture observation information daily on all portions of at least one area of coverage of the celestial body, by saturation.

Advantageously and according to the invention, each satellite is allowed to describe a natural orbital trajectory without active correction of this orbital trajectory.

Advantageously and according to the invention, at least one launcher is used, and multiple satellites of a satellite fleet are grouped in it to be placed in orbit around the celestial body.

The preferred embodiment of the invention foresees that the fleet is launched by groups of about ten satellites using small launchers. About twenty launch missions are therefore necessary to place a fleet of 200 satellites in orbit. The total cost of these launch missions is often less than the cost corresponding to the use of a single traditional launcher such as the Ariane launcher. Additionally, although the risk of failure of a small launcher is often higher that that of a single specialized launcher, it is not critical, contrary to that of a single specialized launcher. In fact, the potential for loss of satellites in quantity is less than with a single specialized launcher. The invention thus makes it possible to reduce the overall risk of the investment in launching the fleet of satellites into space.

Advantageously and according to the invention, the reflecting devices of the said satellites are fitted into each other in a stack on a platform of a launcher, and the receiving devices of the said satellites are placed on the platform around the stack, each of them being placed on a suitable ejecting device to propel it outside the launcher when it is put into orbit.

The invention extends to a fleet of satellites according to the invention, placed in at least one orbit around a celestial body.

Advantageously, in a fleet according to the invention, the satellites are placed in at least one non-geostationary orbit, and the fleet comprises a suitable number of satellites to make it possible statistically to capture observation information daily on all portions of at least one area of coverage of the celestial body, by saturation.

The invention also concerns an observation satellite, a method and a fleet of satellites, with, in combination, all or some of the characteristics above or below.

Other objects, characteristics and advantages will appear on reading the following description, which is given as a non-limiting example, and which refers to the attached figures, in which:

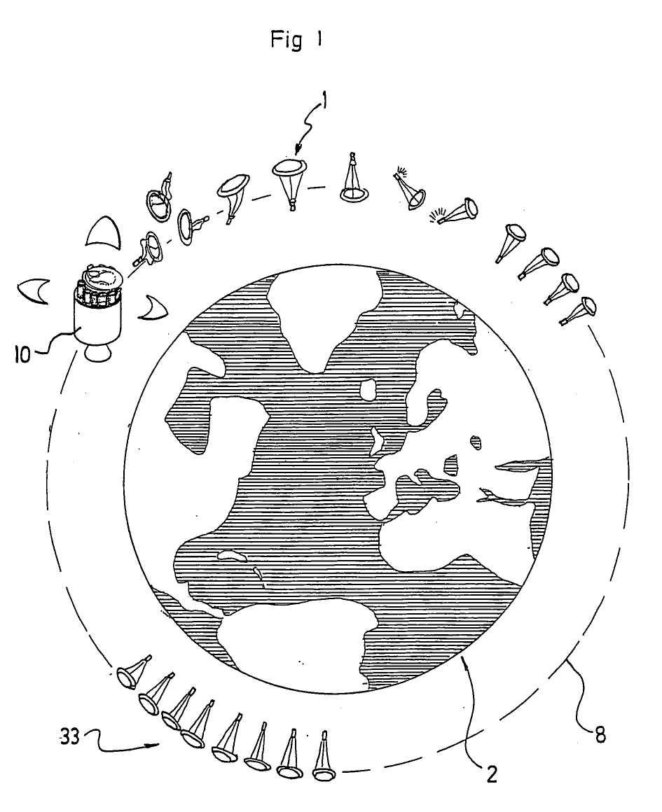

FIG. 1 is a schematic view representing a fleet of observation satellites according to the invention in the course of being launched and put into orbit,

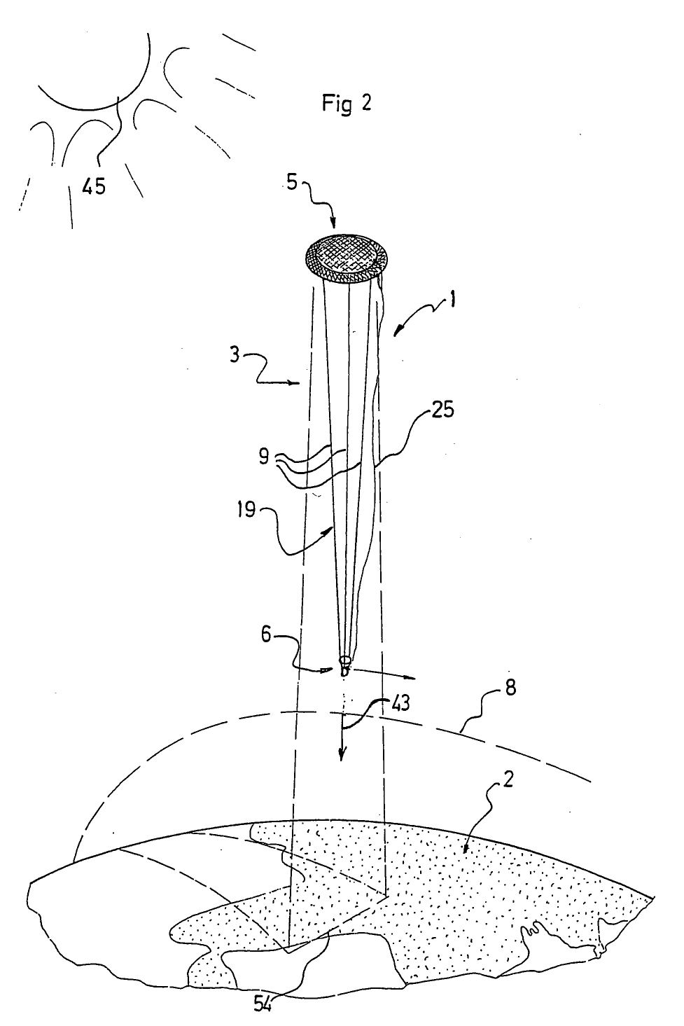

FIG. 2 is a schematic, perspective view of an observation satellite according to the invention, of which the capture system is in the deployed state and according to an ideal aiming orientation,

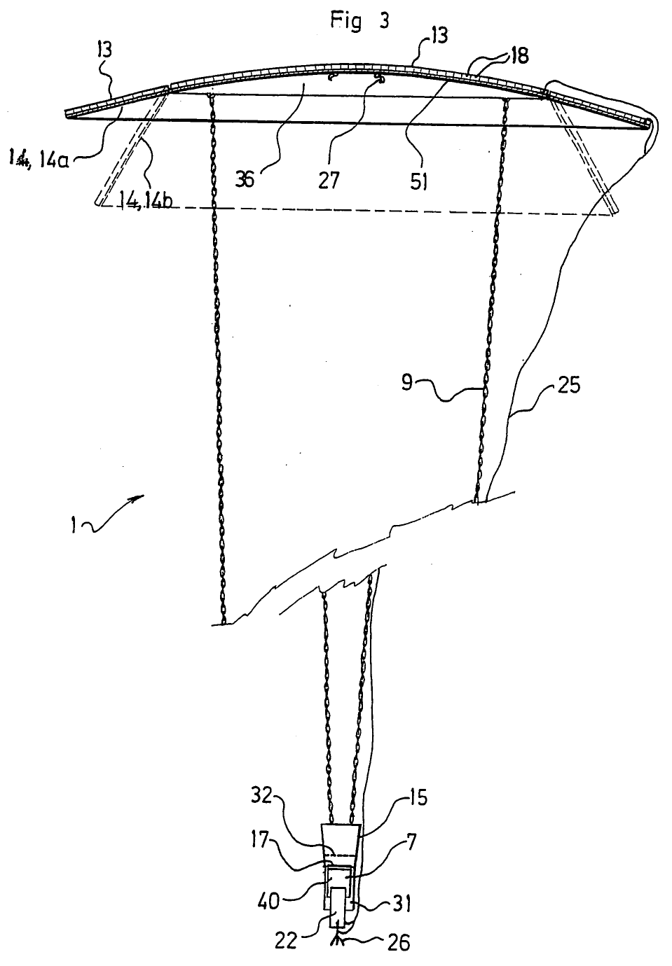

FIG. 3 is a schematic view of an axial cross-section of the satellite of FIG. 2,

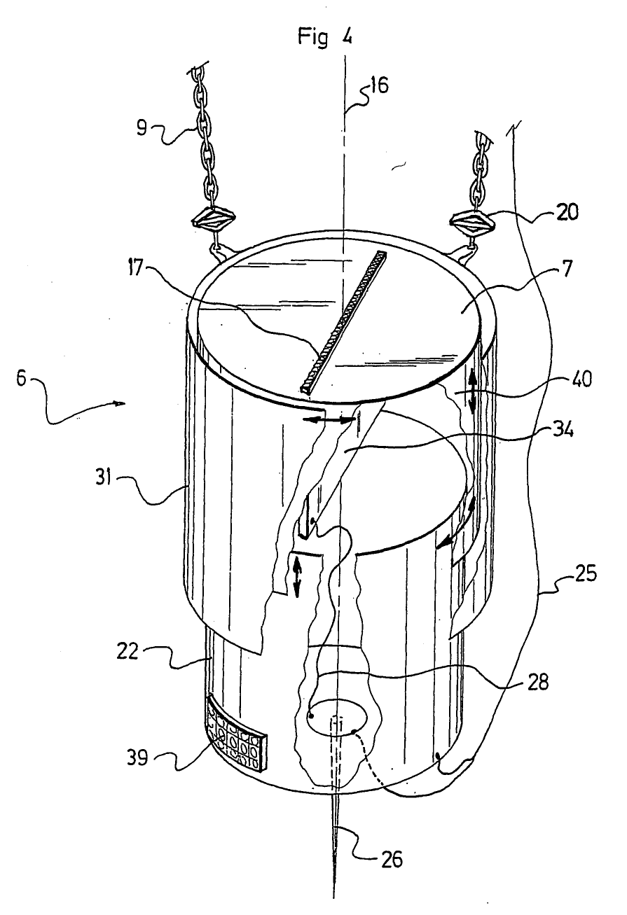

FIG. 4 is a schematic, perspective view showing a receiving device according to an embodiment of a satellite according to the invention,

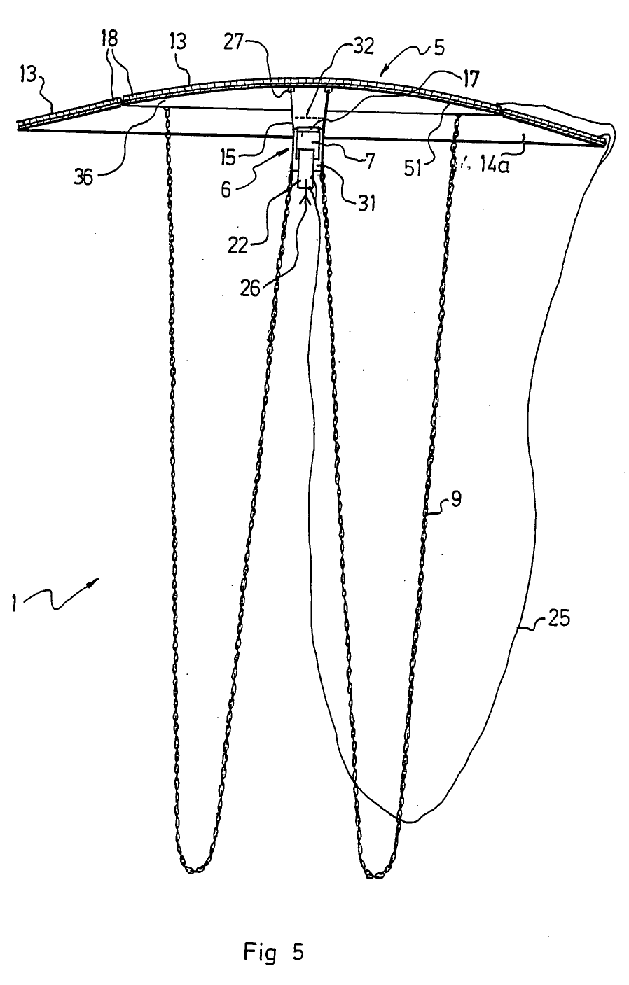

FIG. 5 is a schematic view of an axial cross-section of the satellite according to the invention, of which the capture system is in the folded state, according to a first way of positioning for storage and/or loading into the launcher for launching,

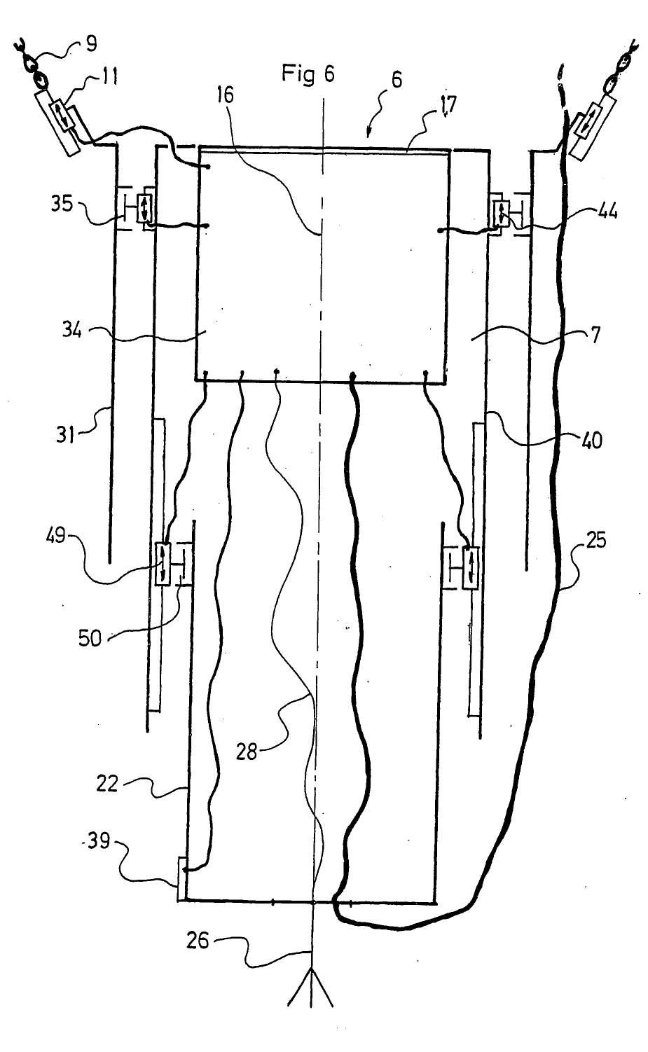

FIG. 6 is a diagram of the drive train of the components of the receiving device,

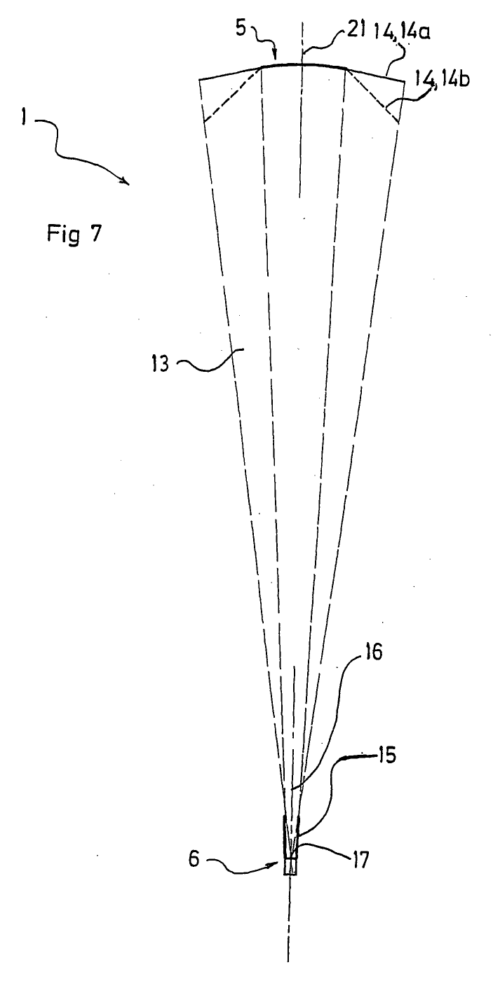

FIG. 7 is a diagram showing the general geometry of the capture system in the deployed state of a satellite according to the invention, only the reflecting surface, the blinker, the gutter, the receiving device and the detecting component being shown,

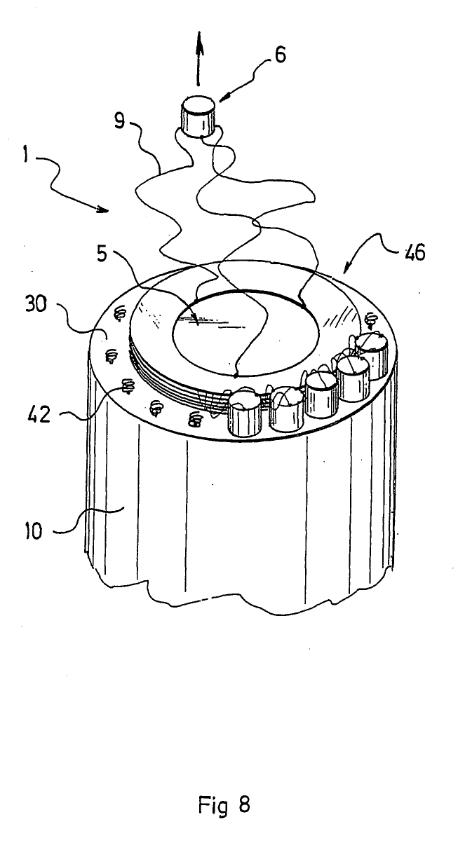

FIG. 8 is a schematic, perspective view of a group of satellites according to the invention in the folded state, according to a second way of positioning for loading into a launcher for launching,

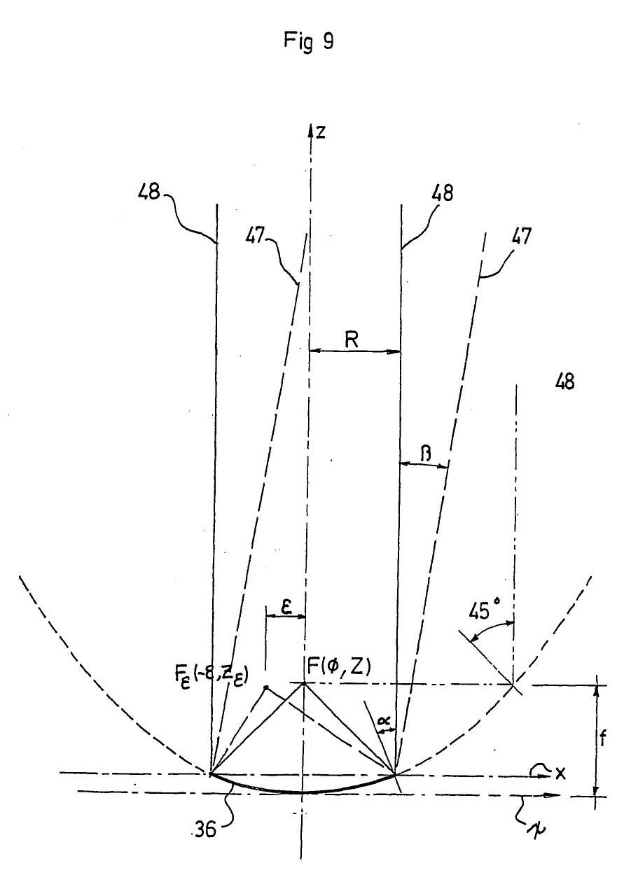

FIG. 9 is a diagram in axial cross-section of the reflecting surface in an embodiment according to which the reflecting surface is in the form of a paraboloid of revolution, illustrating several geometrical and optical parameters of this reflecting surface.

It should be noted that not all the components of the satellite are systematically represented in the figures, for clarity.

The figures are not to scale or proportional, for illustrative purposes and clarity.

FIG. 1 represents a celestial body 2 and satellites 1 which are in place or in the course of being launched and put into orbit according to an orbit 8 around the celestial body 2, by a launcher 10.

In this case, the celestial body 2 is the Earth, but it can be, according to other embodiments, another planet, a star or a celestial body of another type, provided that it generates a sufficient gravity field to allow at least partial stabilization of the satellites 1 by gravity gradient, as described below.

A single orbit 8 is represented in FIG. 1. However, the fleet 33 of satellites 1 can be distributed over several orbits 8. For example, the orbit 8 can be a low orbit or a medium orbit. For example, in the case of observation of the main parts of the continental masses except Antarctica, the satellites 1 can be placed in medium height inclined orbits 8 or low inclined orbits 8.

A single launcher 10 is shown in FIG. 1. However, it should be noted that there is nothing to prevent placing several groups of satellites 1 in the same orbit 8 in several successive or simultaneous launches, using several launchers 10.

The various phases of putting the satellite 1 into orbit according to the preferred embodiment of the invention are shown in FIG. 1. The satellite 1 is first ejected from the launcher 10. It then orients itself under the effect of the gravity gradient so that it is completely or partially stabilized, in particular using a system to damp or amplify the oscillations and by friction in the residual atmosphere as described below, around an equilibrium position so that it can observe the celestial body 2. This equilibrium position corresponds to an ideal aiming orientation in which the capture system 3 points in the direction of the center of mass of the celestial body 2. However, a slight angular deviation of the satellite 1 relative to this orientation is tolerated. There is therefore a range of aiming orientations, close to the ideal aiming orientation, for which the capture system 3, given sufficient stabilization as described below, can capture information in relation to an area of the celestial body 2 with a minimum degree of fidelity as required by the application of the invention (cartography, meteorology, etc.).

It can happen, as shown in FIG. 1, that the satellite stabilizes itself by gravity gradient around an equilibrium position which is reversed relative to the ideal aiming orientation. As described below, a device 39 of the satellite 1 can then tip the satellite 1 into the desired orientation.

FIG. 2 shows an observation satellite 1 according to the invention observing the celestial body 2 after being placed in orbit.

The observation satellite 1 consists essentially of a capture system 3. Unlike known observation satellites such as SPOT 4, it has no platform, structure or rigid frame. Consequently, a satellite 1 according to the invention is very light.

The information capture system 3 comprises a reflecting device 5, with a reflecting surface 36 which is suitable to be able to reflect the electromagnetic radiation belonging to the spectral range to be observed; a receiving device 6, which carries a suitable detecting device 7 to capture the information from the electromagnetic radiation 47, 48 belonging to the spectral range to be observed; and a linking mechanical system 19, which moors the reflecting device 5 and receiving device 6 to each other.

The capture system 3 is capable of being placed, as described below, in a folded state in the launcher 10, and of deploying itself when it is put into orbit. To do this, the linking mechanical system 19 is preferably flexible, so that it extends bit by bit as far as an equilibrium position under the tension resulting from a gravity gradient between the receiving device 6 and reflecting device 5. The capture system 3 is then in the deployed state, and is able to capture information.

In this deployed state, the capture system 3 is in a very elongated form, in particular so that it can be deployed and stabilized in a functioning relative position and according to an aiming orientation under the effect of the gravity gradient which the celestial body 2 generates. It thus has a longitudinal direction, which tends to align itself with the gravity gradient when it is in an aiming orientation.

The reflecting surface 36 is convergent, so that it has at least one area in which the electromagnetic radiation 47, 48 is focused. When the receiving device 6 and reflecting device 5 are in the functioning relative position, the detecting device 7 is at least placed near the focusing area of the reflecting surface 36. To be convergent, the reflecting surface 36 is also concave. It preferably has symmetry of revolution around an axis 21, called the axis 21 of the reflecting device, which forms its optical axis.

The reflecting device includes a reflecting component, called the parabolic reflector 51, with a concave face.

The concave face of the parabolic reflector 51 is preferably smooth, continuous and in the form of a paraboloid of revolution. The reflecting surface 36 can then be implemented by aluminizing the said concave face of the parabolic reflector 51 for observation in the visible range. Other materials like aluminum can alternatively be fixed to the concave face of the parabolic reflector 51 to form a film which forms a reflecting surface 36 which is able to reflect electromagnetic radiation belonging to the spectral range to be observed. The materials which are used to implement this film can be of metallic, ceramic or other type depending on the spectral range to be observed.

It is unnecessary to add a film of reflective material to the reflecting device 5 in the case that the material which forms the parabolic reflector 51 is itself able to reflect the electromagnetic radiation belonging to the spectral range to be observed. In this case, the concave face of the parabolic reflector 51 can form the reflecting surface 36 directly.

Also, the concave face of the parabolic reflector 51 can be different from the smooth, continuous form which is recommended for observation in the visible range. For example, in the case of observation in the radio wave range, the concave face of the parabolic reflector 51 can be formed from a mesh structure, e.g. of metallic material.

It should be noted that the reflecting surface 36 can have any other structure which is able to reflect electromagnetic radiation belonging to the spectral range to be observed toward the receiving device 5, to make it possible to capture the information to be captured.

For example, the parabolic reflector 51 can be of resin or any other material which is sufficiently rigid to be able to maintain the functional geometry of the reflecting surface 36 once the satellite 1 has been placed in orbit.

The thermal inertia of the parabolic reflector 51 must also be as low as possible, so that the reflecting surface 36 rapidly resumes its functional geometry following a thermal fluctuation. More particularly, the parabolic reflector 51 must allow the reflecting surface 36 to resume its functional geometry in less time than is required for the satellite 1 to pass through an illuminated segment of orbit between two segments of orbit in eclipse.

To observe the celestial body 2, the reflecting surface 36 of the satellite 1 must be oriented toward the surface of the celestial body 2, to capture the electromagnetic radiation coming up from the celestial body 2. The aim of the capture system 3 is naturally oriented in the direction of the celestial body 2 under the effect of the gravity gradient.

The linking mechanical system 19 is formed from multiple threadlike suspension lines 9 which are joined, at one of their extremities, to the reflecting device 5 on the outside of the reflecting surface 36, e.g. at its periphery, to avoid any development of interfering stresses which could damage its functional geometry. The other extremity of each of the threadlike suspension lines 9 is joined to the receiving device 6, preferably on a bracket 31 of the receiving device 6 as described below.

The receiving device 6 includes at least one component 17 which has at least one detector which is suitable for observation of one or more types of electromagnetic radiation which are of interest. The detecting component 17 preferably has multiple detectors which are arranged in a plane, called the incidence plane, which is intended to be placed orthogonally to the axis 21 of the reflecting device 5 and at the focal distance of the reflecting surface 36. The reflecting device 5 and receiving device 6 are then in the functioning relative position.

Preferably, the detectors of the detecting component 17 are arranged in a row of detectors which are intended to be oriented perpendicularly to the trajectory over the ground of the satellite 1 when the capture system 3 of the satellite 1 is placed in the aiming position. This configuration is particularly suitable for applications in cartography and imaging of areas of the celestial body 2. The row of detectors can in fact capture a two-dimensional image representing an area of the celestial body 2 by sweeping observation of this area by the satellite 1 flying over this area. In the case that the reflecting surface 36 has symmetry of revolution around the axis 21 of the reflecting device, the detectors are preferably distributed in equal numbers on one side and the other of an axis, called the detection axis 16, which is perpendicular to the incidence plane. The detection axis 16 is intended to align itself with the axis 21 of the reflecting device when the reflecting device 5 and receiving device 6 are in the functioning relative position. The detection axis 16 and the axis 21 of the reflecting device are suitable to align themselves with an axis 43, called the aiming axis 43, when the latter is placed according to an aiming orientation.

In practice, for example to observe the celestial body 2 in the visible range, the detecting component 17 can be a charge transfer device, called a CCD strip, containing at least one row of charge transfer detectors, called CCD detectors.

It should be noted that the detectors of the detecting component 17 may be other than CCD detectors. The detectors of the component 17 may be of any type which is suitable for a spectral range to be observed, such as the microwave range or infrared range.

In the case of observation in the microwave range (this variant not shown), the detecting component includes one or more waveguides acting as detectors. These waveguides are of suitable dimensions for the wavelengths of the microwave radiation to be captured, and preferably in the form of a horn.

The waveguides are integrated with each other by a suitable rigid structure. The waveguides are preferably arranged in a row in the incidence plane, thus forming a battery of waveguides.

In the case of observation in the infrared range (this variant not shown), the detectors of the detecting component are, for example, microbolometers.

The detectors of the detecting component 17 can also be arranged in one or more rows, or in any other arrangement as a function of the reflecting surface 36 and the type of observation to be carried out, according to the application.

For example, the CCD strip can include several rows of charge transfer detectors. These rows are preferably arranged parallel with each other on the incidence plane, so that they can capture in succession the same portion of the area being flown over because of the movement of the satellite 1. This technique, commonly called TDI (time delay integration), makes it possible to obtain a better signal/noise ratio than by simple capture with a single row of cells.

The receiving device 6 can also include two detecting components 17, which are arranged on one side and the other of the detection axis 16, so that they present their rows of detectors in parallel with each other. This makes it possible to obtain a two-dimensional, stereoscopic representation of the area of the celestial body 2 being flown over when the rows of detectors are placed approximately perpendicular to the trajectory of the satellite 1 over the ground.

Studying the optical geometry of the reflecting surface 36 makes it possible to determine the general dimensions of the capture system 3. If f is the focal distance, and D is the diameter of the reflecting surface 36, the ratio ρ=f/D must be great enough so that it makes it possible, on the one hand, to orient and stabilize, at least partially, the satellite 1 by gravity gradient in the aiming position, and on the other hand, to tolerate the defocusing of the incidence plane compatibly with the efficiency of this stabilization and with the uncertainty of the length of the linking mechanical system 19 which is used. A high ratio ρ=f/D makes it possible to use a linking mechanical system with a significant uncertainty of length, such as a linking mechanical system 19 described below, i.e. one which is flexible to allow loading in compact form in the launcher.

Studying the optical geometry of the reflecting surface 36 also makes it possible to determine the defocusing of a detector of the detecting component 17 from its observation position, which is shifted in the incidence plane relative to the detection axis 16.

In particular, the ratio ρ=f/D must be of the order of the ratio between the size of the detectors of the detecting component 17 and the observation wavelength λ. The observation wavelength λ here can be interpreted as the mean wavelength of the electromagnetic radiation to be observed. The defocusing effects and the parameters which make it possible to calculate the ratio ρ=f/D are given below with reference to FIG. 9.

Let there be a reflecting surface 36 in the form of a paraboloid of revolution with radius R. Its form in an axial plane is given by:

z(x)=px²

All the incident radiation 48 which is parallel to the optical axis of the reflecting surface 36 converges on the focus F of the reflecting surface 36. Assuming that the slope at the opening R is 45°, the maximum height z of the reflecting surface 36 corresponds to the height f of the focus F (because the rays which touch the exterior edge return to the horizontal). In this case:

$$\frac{d}{d x} z ( x ) = 2 px = 1$$

so:

$$f = z ( \frac{1}{2 p} ) = \frac{1}{4 p}$$

An important parameter of the paraboloid is its relative opening ρ:

$$ρ = f / D = \frac{f}{2 R}$$

The angle α of the tangent at the edge of the paraboloid is given by:

$$\frac{d z}{d x} ( R ) = 2 ρ R = \frac{R}{2 f} = \frac{1}{4 ρ} = tan ( α )$$

Changing the origin of the ordinates by taking them from the edge of the paraboloid gives:

$$Z = \frac{R}{tan ( 2 α )}$$

The point F, of abscissa 0 (on the axis of the paraboloid) and ordinate Z, is the focal distance of the reflecting surface 36. The incidence plane of the detecting component 17 is therefore placed approximately at the distance Z from the reflecting surface 36 when the reflecting device 5 and receiving device 6 are in the functioning relative position.

Reflected radiation from incident radiation 47 which deviates by an angle β relative to the axial radiation 48 is focused on a point Fε which is distinct from the point F. The point Fε effectively represents a lateral shift of value ε. Similarly, the crossing height is no longer exactly Z, but Zε. By elementary trigonometry:

$$ɛ = R \frac{sin ( 2 β )}{sin ( 4 α )}$$

$$Also , \\ Z - Z ɛ = \frac{R}{tan ( 2 α )} - \frac{R + ɛ}{tan ( 2 α + β )}$$

By developing this second-order equation in β, we obtain an equation of the form:

Z−Zε=cβ²

where c represents a real constant.

This formula gives the defocusing Z-Zε for an observation in a shifted position in the incidence plane relative to the detection axis 16 when the incidence plane is at the focal distance. This defocusing Z-Zε is at its maximum value for a detector at the end of the row of the detecting component 17. This detector is then at a position of lateral shift of value εₘₐₓ relative to the detection axis 16.

The lateral shift of value εₘₐₓ thus represents half the length of the row of detectors as a function of a desired resolving power of value β. If the observed wavelength is λ and the opening of the reflecting surface is D=2R, the resolving power is:

$$β \approx \frac{λ}{2 R}$$

The observation distance outside axis for such a resolving power is:

$${ɛ}_{max} \approx \frac{λ}{sin ( 4 α )} = λ \frac{ {( 16 {ρ}^{2} + 1 )}^{2}}{16 ρ ( 16 {ρ}^{2} - 1 )}$$

Since ρ is in general greater than 4, the ones are negligible, and εₘₐₓ≈ρλ.

For example, a ratio ρ=f/D of 10 can be chosen, for a wavelength of 0.5 microns and a detector size of 5 microns. If a detecting component 17 comprises a row of n=1000 detectors, it is then possible to work with 500 detectors on one side and the other of the detection axis 16. If necessary, the defocusing Z-Zε is compensated for by an optical correction device (not shown) which is placed near the detecting component.

For an Earth observation telescope which is as simple as possible, but has submetric capacity, for example a parabolic reflector 51 with a reflecting surface 36 of diameter about 50 cm and a focal distance of 5 meters (to conform to the ratio between useful wavelength and size of the detecting component 17) is chosen.

For example, the detecting device 7 can include one or more strips of 36 mm, each consisting of 6000 6 micron detectors end to end. With a focal distance of 5 m, the tolerance on the length of each threadlike suspension line 9 can reach 50 microns. Such a variation of distance can be the result, for example, of a straightness fault of the order of 1 cm in the median part of the threadlike suspension line 9. The tensile force T which is exerted on the threadlike suspension lines 9 due to the gravity gradient is given by:

$$T = gm \frac{{R}^{2} h}{{( R + H )}^{2} R}$$

where h is the distance between the centre of mass of the reflecting device 5 and the centre of mass of the receiving device 6, m is the mass of the satellite 1, g is the acceleration at the surface of the Earth, R is the radius of the Earth and H is the flying altitude.

This force is much weaker than on the ground. For example, for an orbit at an altitude of the order of 1,000 to 2,000 kilometers, the tension T is typically of the order of 1,000,000 times weaker than on the ground. Such a tension corresponds to time constants which are 1,000 times greater. Thus the period of free oscillation of the pendulum which the satellite 1 constitutes is of the order of 30 minutes.

The threadlike suspension lines 9 must be rigid under traction (i.e. have negligible elasticity under traction), and flexible and inelastic under flexion (i.e. have negligible rigidity under flexion). Preferably, they are equally flexible and inelastic under torsion, at least within a certain range of angular amplitude, and their properties under compression are unimportant in the context of the invention. In any case, the threadlike suspension lines 9 must be able to moor the reflecting device 5 and receiving device 6 to each other, while keeping them in the functioning relative position under the effect of the gravity gradient, without generating interfering stresses. In practice, the threadlike suspension lines 9 can be formed from chains, cables or wires of suitable materials.

The threadlike suspension lines 9 are formed from one or more materials which are preferably chosen to have the lowest possible thermal inertia. For example, the threadlike suspension lines 9 are formed, as shown in FIG. 6, of chains of which the links are of ceramic, with excellent rigidity under traction and very low thermal inertia. In this way, a difference of exposure to thermal radiation between the threadlike suspension lines 9 has no adverse effect on the equilibrium of the assembly or on keeping the reflecting device and receiving device 6 in the functioning relative position.

Preferably, the threadlike suspension lines 9 are also formed of one or more materials which are suitable for absorbing the electromagnetic radiation belonging to the spectral range to be observed, so that they do not reflect interfering electromagnetic radiation onto the detecting component 17.

It should be noted that implementing the threadlike suspension lines 9 in the form of chains makes it possible to reduce any residual rigidity under flexion, torsion (at least in a certain range of angular amplitude) and compression. The chains also dissipate excess mechanical energy more easily. It is more difficult for them to become entangled when the satellite 1 is in the folded state as described below. A chain also has a more reliable structure provided that each of the links has two strands. Breaking one of the strands does not necessarily cause the suspension line 9 to break.

Preferably, the links of the chain each include two knives, each knife being formed of a projecting edge in an interior part of the loop of the link. The knives are arranged on one side and the other of the link so that their edges are parallel to each other. Thus two knives of two distinct links cross each other in a contact which is approximately point-like at each articulation of successive links of a chain when it is subjected to a tensile stress. This makes it possible to reduce the uncertainty about the functional length of the links of the chain compared with that of traditional links, of which the articulation between two links occurs in a more irregular contact area. The functional length of the links which form the suspension lines 9 according to the invention thus corresponds to the distance between the two projecting edges which form the knives of each link.

Depending on the applications (meteorology, cartography, etc.) of the satellite according to the invention and the degree of fidelity of capture which they require, a tolerance of defocusing of the incidence plane and of faulty alignment of the axis 21 of the reflecting device and the detection axis 16 is accepted. There is thus a range of relative positions of the receiving device 6 relative to the reflecting device 5 corresponding to a functioning relative position. Effectively, it is enough that the incidence plane should be placed near enough to the focal distance, and that the detection axis 16 should be sufficiently aligned with the axis 21 of the reflecting device 5 to make it possible to capture information, i.e. to capture it while reaching a minimum fidelity threshold which the application (meteorology, cartography, etc.) requires.

It should be noted that the uncertainty about the length of the suspension lines 9 must be low enough so that the reflecting device 5 and receiving device 6 can be placed in a functioning relative position as described above.

Thus the links which form the suspension lines 9 must be formed of one or more materials which give the links suitable rigidity so that they are not significantly deformed either plastically or elastically under the tension resulting from the gravity gradient which stabilizes the satellite 1 according to the invention in orbit. In particular, the knives of the links must be sufficiently rigid so that they are not blunted or deformed under the tension of the threadlike suspension lines 9 once the satellite 1 is placed in orbit.

The edge of the parabolic reflector 51 can be of a form which is adapted to have a peripheral fixing bulge (not shown in the figures) to which the threadlike suspension lines 9 can be fixed. The fixing bulge must be sufficiently rigid to prevent deformation of the reflecting surface 36 despite the stresses under the tension of the threadlike suspension lines 9 once the satellite according to the invention is placed in orbit. Preferably, the links at the extremity of each suspension line 9 at the reflecting device 5 are fixed to the fixing bulge of the parabolic reflector 51 via fixing loops (not shown in the figures) which are integral with the said fixing bulge. The fixing loops can be formed of the material of the parabolic reflector 51. Alternatively, they can be fixed to it, e.g. by adhesive or welding. Like the links of the chains which form the threadlike suspension lines 9, the loops can have a knife to minimize the defocusing of the detecting component 17 relative to the reflecting surface 36. Alternatively, the links at the ends of the suspension lines 9 can be directly welded or glued to the parabolic reflector 51. If the parabolic reflector 51 is of resin, the links can be embedded in the mass of the fixing bulge of the parabolic reflector 51.

The threadlike suspension lines 9 are preferably fixed to the bracket 31 via a pivot link, a free ball link or any other link which avoids the development of interfering stresses in the threadlike suspension lines 9 and bracket 31. For example, each threadlike suspension line 9 can be fixed to a loop of the bracket 31.

In combination, the free extremity of each threadlike suspension line 9 can be joined to the bracket 31 of the receiving device 6 via an adjusting motorized linear actuator 11, e.g. a piezoelectric linear actuator 20 with no parts with dynamic friction, as described in WO 02/084361. Such a piezoelectric linear actuator 20 can also be interposed at any place along the length of the threadlike suspension line 9, or even between the upper extremity of the threadlike suspension line 9 and its link to the parabolic reflector 51. Each piezoelectric linear actuator 20 is controlled from an electronic card 34, to which it is preferably connected by an electrical conducting wire (shown in FIG. 6 but not in FIG. 4). The piezoelectric linear actuators 20 are preferably controlled from the electronic card which is connected to the detecting device 7, as described below.

The length of each threadlike suspension line 9 can be adjusted individually to allow the precise alignment of the detection axis 16 with the axis 21 of the reflecting device in orbit. A simultaneous adjustment of the length of all the threadlike suspension lines 9 also makes it possible to make the distance which separates the detecting device 7 from the reflecting surface 36 vary. It is thus possible to correct the position of the receiving device 6 relative to the reflecting device 5, to place them in a functioning relative position.

Each piezoelectric linear actuator 20 can be integrated with the bracket 31 by adhesive, welding or another suitable method of fixing. The bracket 31 has overall symmetry of revolution around the axis 16. The piezoelectric linear actuators 20 are preferably distributed at uniform angles around the bracket 31. The threadlike suspension lines 9 are integrated with the piezoelectric linear actuators 20 by adhesive, welding or another suitable method of fixing.

The bracket 31 is, for example, in the form of a hollow cylinder, an annular structure or other, and an assembly bush 40, also preferably of cylindrical form. In the case that the detecting component 17 comprises one or more rows of detectors, the bush 40 is of a suitable form to carry the detecting component 17 so that it extends radially relative to the detection axis 16 and orthogonally to this detection axis 16.

The assembly bush 40 is fitted so that it can rotate freely relative to the bracket 31 by means of a frictionless pivot link, so that the angular movement of the detecting device 7 around the ideal aiming axis 43 is approximately independent of that of the assembly consisting of the reflecting device 5, the linking mechanical system 19 and the bracket 31. The link between the assembly bush 40 and the bracket 31 can be implemented by a suspension device 35 with negligible friction. For example, the suspension device 35 can be of ball bearing or roller bearing type.

Preferably, the suspension device 35 is electromagnetic. For example, a ring can be fitted around the assembly bush 40 so as to extend radially and orthogonally to the detection axis 16 in a groove which is formed between two annular stops which are fitted integrally with the bracket 31 and extend radially and orthogonally to the detection axis 16 around the assembly bush 40. The ring and stops preferably consist of materials each of which has a permanent magnetic dipole. The orientation of the dipoles of the ring and stops is suitable for generating repulsive magnetic forces between the assembly ring and stops. These forces must be sufficient to keep the assembly bush 40 in the detection axis 16, and the detecting component 17 at the focal distance of the reflecting surface 36, without contact between the said ring and the said stops.

To be able to readjust the position of the detecting component 17 in the case that it has been defocused, the said ring is preferably fitted so that it slides on the assembly bush, so that it can be displaced along the detection axis 16 under the control of a motor 44. This makes it possible to make fine adjustments of the position of the detecting component 17 at the focal distance of the reflecting surface 36. In practice, the said motor 44 is preferably electric and integrated with the assembly bush. It drives a pinion which meshes with a rack which is integrated with the said ring. This system can be used as an alternative to or in combination with the system to adjust the length of the threadlike suspension lines 9 using adjusting motorized linear actuators 11 to carry out an action to focus the detecting component 17.

The receiving device 6 includes a motorized device to orient the detecting device 7 around the detection axis 16. This motorized orientation device is suitable to be able to adjust the angular position of the detecting component 17 around the detection axis 16. When the capture system is in the aiming orientation, this makes it possible to put the detecting component 17 back into an optimum angular position for capture relative to the trajectory of the satellite when it leaves this position. In the case that the detecting component 17 comprises a row of detectors, the optimum position corresponds to the position in which the row of detectors is orthogonal to the trajectory of the satellite 1 over the ground. The orthogonality fault can be detected, for example, by analysis of telemetry which is received on the ground.

In practice, the motorized orientation device can be implemented using a counterrotating part 22 which is carried by the bush 40 on its lower part. This counterrotating part 22 is fitted so that it can rotate relative to the bush 40 around the detection axis 16. An electric motor 50, called the counterrotation motor 50, makes it possible to make the counterrotating part 22 turn relative to the assembly bush 40 around the detection axis 16. This makes it possible to make the assembly bush 40 rotate relative to the bracket 31 without inducing torque on the bracket 31. The link between the bush 40 and the counterrotating part 22 preferably has the least possible friction, to minimize the necessary energy for the counterrotation motor 50 to drive them relatively in rotation. In practice, the counterrotation motor 50 can be carried by the bush 40, and drive a pinion which meshes with a crown gear which is integrated with the counterrotating part 22.

Also, the counterrotating part 22 is preferably fitted on the bush 40 to be able to slide parallel to the detection axis 16 according to a certain amplitude, under the control of a motorized device 49 which is suitable for driving these two parts in translation relative to each other, or conversely for damping the relative translation movement.

Once the satellite 1 is placed in orbit, its pitching and rolling movement can be of pendular type around an equilibrium position corresponding either to an aiming orientation of the satellite 1, or to a head to tail orientation of the satellite 1 relative to the aiming orientation.

Damping can be obtained by making a mass ascend and descend progressively and periodically along the detection axis 16 of the satellite. This makes it possible to vary the moments of inertia of the satellite 1 between two values, called minimum and maximum, according to the rolling and pitching axes. This movement must be carried out at a frequency which is double that of the pendular oscillation of the satellite 1, so that the moment of inertia of the satellite according to the rolling and pitching axes (the yawing axis corresponding to the detection axis 16 and the axis 21 of the reflecting device) is at a minimum value when the oscillation of the satellite 1 reaches the maximum amplitude, and so that the moment of inertia is at a maximum value when the satellite returns temporarily to an equilibrium position. Similarly, amplification of the pendular movement of the satellite 1 is obtained when the periodic movement which is imparted to the mass is such that the moment of inertia of the satellite according to the rolling and pitching axes is at a maximum value when the oscillation of the satellite 1 reaches the maximum amplitude, and that the moment of inertia is at a minimum value when the satellite returns temporarily to an equilibrium position.

It is thus useful to be able to synchronize the periodic movement of the component with respect to the pitching and/or rolling oscillation of the satellite. To do this, several solutions are possible. For example, it is possible to provide that the periodic movement of the component is initiated by remote control from a terrestrial station which has a telescope which makes it possible to capture the oscillating movement of the satellite 1 directly. Alternatively, a piezoelectric sensor 20 can be fixed on one of the suspension lines 9, to be able to capture its instantaneous tension. This measurement can be processed on the ground or on board the satellite 1 by a system which is able to deduce the phase of the pendular oscillation of the satellite 1, and thus able to initiate, at the appropriate moment, the periodic movement of the mass, so as to make possible either a damping or an amplification of the oscillation, as a function of the remote command which is received from a ground station.

It should be noted that the damping or amplification system as described above does not make it possible to damp a pitching or rolling oscillation if the latter consists of multiple pendular components of distinct phases, for example when the satellite 1 describes a circular oscillation around the yawing axis 43. In fact, damping a pendular component of such an oscillation using the damping system as described causes amplification of another pendular component which is out of phase with the first.

For many applications, in particular observation of the surface of the celestial body 2 in the visible range, a pitching and/or rolling oscillation of the capture system 3 not exceeding an amplitude of 5 degrees is acceptable, taking account of the long oscillation period of the capture system 3 (of the order of 30 minutes). In fact, the whip pan effect due to the oscillation of the capture system during the observation is then negligible, and the obtained information then achieves a minimum degree of fidelity as required by the application. Each of the positions which are then taken by the capture system 3 in the course of such an oscillation corresponds to an aiming orientation.

The damping or amplification system can thus be used to make the oscillation amplitudes of the various pendular components uniform, in such a way that the resulting oscillation amplitude remains below a threshold value. This threshold value is determined according to the level of fidelity which the application (cartography, meteorology etc.) requires. In the case that the amplitudes of the various pendular components are too great for keeping the resulting oscillation below the threshold value to be possible, it can be expected that the oscillation of the satellite 1 is naturally damped by friction in the residual atmosphere in orbit.

The detecting device 7 includes, below the strip of CCD detectors and within the assembly bush 40, an electronic card 34 which is connected to the detectors of this strip to receive and process signals from them for information capture. The information capture electronics and the electronics making it possible to manage the satellite 1 itself and its communication functions for telemetry and remote control are preferably centralized on this electronic card 34.

An antenna 26 of a telemetry system is carried on the lower part of the counterrotating part 22. The antenna 26 is thus advantageously oriented toward the celestial body 2 and the ground stations. Electrical conductors, for example by means of an electrical wire 28, connect the antenna 26 to the electronic card 34. This antenna 26 makes it possible to send the captured information to, for example, the celestial body 2 for utilization. It can also receive certain functions for remote control of the satellite 1.

The reflecting device 5 can have, opposite the reflecting surface 36, a photovoltaic surface 13 consisting of photovoltaic cells 18 which are suitable for receiving light from a light source 45 such as, for example, the Sun, and for supplying electrical energy to the satellite 1 from this light radiation. The photovoltaic surface 13 is fixed on the parabolic reflector 51 so that it is exposed to the source 45 when the reflecting surface 36 is oriented toward the celestial body 2.

Thus the photovoltaic surface 13 is preferably strapped to one face of the parabolic reflector 51, opposite the reflecting surface 36.

The photovoltaic cells 18, via the photovoltaic surface 13, are connected by an electrical power supply cord 25 to the detecting device 7, to supply electrical power to it. The length of this electrical power supply cord 25 must be enough not to interfere with the optical functioning of the capture system 3 in the deployed state. Its mass and properties must also be adapted not to disturb the mechanical equilibrium of the satellite 1. This electrical power supply cord 25 may be duplicated for increased reliability. Also, the power supply cord 25 may be connected electrically to the photovoltaic surface 13 by means of a free ball link which is fixed in the axis 21 of the reflecting device.

Preferably, the receiving device 6 is adapted to limit the angular positions which the detecting device 7 takes relative to the bracket 31 of the receiving device 6 to a range of angular positions with a maximum amplitude between 90 and 360 degrees. This makes it possible to prevent the electrical power supply cord 25 winding itself around the capture system 3 because of a rotation of the detecting device 7 relative to the bracket 31. Means of measuring the angular position of the detecting device 7 relative to the bracket 31 can be used to do this.

A peripheral mask, called the gutter 14, can be provided at the periphery of the reflecting surface 36 so as to prevent or limit the incidence of interfering electromagnetic radiation from sources other than the celestial body 2 on the detecting device 7 and/or the reflecting surface 36. This gutter 14 is in the general form of a ring of constant breadth according to the radial direction, and can consist of any material which has the appropriate optical properties in relation to the electromagnetic radiation to be masked. The gutter is suitable for masking at least the electromagnetic radiation which is liable to be detected by the detecting device 7, i.e. which belongs to the spectral range to be observed.

The gutter 14 can be formed from a band of synthetic material, be semi-rigid and of low thickness. It is fixed rigidly to the periphery of the reflecting surface 36. Preferably, the gutter 14 is fixed to the fixing bulge of the parabolic reflector 51 using adhesive, welding, stapling or any other fixing means which is suitable for the material of which the fixing bulge and gutter consist.

There are two particularly advantageous embodiments of the gutter 14. In the first embodiment, the gutter 14a is in a suitable form to extend the general form of the reflecting surface 36 radially to the axis 21 of the reflecting device. In this way, the reflecting device 5 remains compact. In the second embodiment, the gutter 14b is in a less compact form, making it possible to protect the reflecting surface 36 laterally against possible impacts by micrometeorites or other debris and spatial objects.

In the latter configuration, the photovoltaic cells 18 which the gutter 14b carries are arranged in a complementary orientation to those on the face opposite the reflecting surface 36. The two groups of photovoltaic cells 18 are thus exposed to different incidences of the radiation received from the light source 45. It is thus possible to generate sufficient electric power for operation of the capture system 3 despite the changes of orientation of the satellite relative to the source 45 in the course of its movement in its orbit 8. It should be noted that there is nothing to prevent arranging the photovoltaic cells 18 on other parts of the satellite 1.

Preferably, the receiving device 6 also includes a mask which makes it possible to prevent the direct incidence of electromagnetic radiation which does not come from the reflecting surface 36 on the detecting component 17. This mask, called the blinker 15, is preferably carried by the bracket 31 at its periphery, and extends upward at an appropriate opening angle so that the field of vision of the detecting component is limited exclusively to a solid angle which includes the reflecting surface 36 and the gutter 14. In FIGS. 4, 6 and 8, the blinker 15 is not shown, for clarity of the drawing.

Because the receiving device 6 is placed in the field of vision of the reflecting device 5, it generates a blind area on the reflecting surface 36. Because the blinker 15 is in the form of a truncated cone of revolution, it generates a blind area which is bigger the higher it is. Therefore, a compromise must be found between the height of the blinker 15 and the effective area of the reflecting surface 36. The effective area means the area of the reflecting surface without the blind area. A balance must also be found between the height of the blinker 15 and the diameter of the gutter 14, so that the capture system 3 takes up as little space as possible for loading into the launcher 10. Additionally, the blind area can be made to absorb electromagnetic radiation belonging to the spectral range to be observed, to prevent reflection of interfering radiation at this place.

A filter 32 is arranged between the detecting component 17 and the reflecting device 5, to protect it from thermal infrared radiation from the reflecting device 5.

The masses and spatial geometry of the assembly must allow stabilization by gravity gradient of the satellite 1 in satisfactory circumstances.

One of the advantages of a satellite 1 according to the invention is its capacity for being folded into an extremely compact state for storage and above all for launching. To do this, several variant embodiments are possible. In the variant shown in FIG. 8, multiple satellites 1 conforming to the invention can be stacked one on top of the other in the folded state on a platform 30, to carry out a grouped shot. As can be seen, the reflecting devices 5 are stacked one on top of the other, and the receiving devices 6 are arranged on the periphery of this stack 46 on a platform 30. Springs 42 or other actuators can be provided between the platform 30 and each receiving device 6, to ensure that they are propelled in succession out of the launcher 10, thus driving the rest of the satellite 1 and putting it into orbit.

FIG. 5 shows a variant embodiment in which the receiving device 6, in the folded state of the capture system 3, is fixed to the central part of the reflecting surface 36, which forms the blind area of the reflecting surface 36, and which can have a temporary fixing system 27 for the receiving device 6. The temporary fixing system 27 has controlled means of actuation, making it possible to deploy the assembly after it is put into orbit. In practice, the temporary fixing system 27 can be a pyrotechnic bolt.

It should be noted that it is preferable that the method of putting into orbit should be adapted to limit the torques which are imparted to the satellite 1 while it is being put into orbit. In particular, it is important not to induce rotation of the detecting device 7 around the detection axis 16, which would necessitate too frequent reorientation of a row of detectors of the detecting component 17 perpendicularly to the trajectory of the satellite 1 over the ground, using the motorized orientation device as described.

Typically, with a reflecting surface 36 of 50 cm diameter, and a parabolic reflector 51 of a thickness of the order of 1 mm, a satellite 1 according to the invention can have a total mass less than 5 kg.

The satellites 1 according to the invention have no navigation systems, active aiming control systems or means of propulsion. It is therefore impossible to specify an area to be observed at a given moment to them. Instead, according to the preferred embodiment of the invention, the satellites 1 observe the areas which pass under their respective orbital trajectories 8 (see FIG. 2). These orbital trajectories 8 are natural; the satellites 1 are not guided to follow an orbital trajectory of a given reference.

In the simplest version, the satellite 1 has no battery, and therefore works permanently, provided that the electric power which the photovoltaic cells 18 supply allows.

The satellites 1 are designed to have a low cost of manufacture, launching and use. It is thus possible to form a fleet 33 which includes a large number of satellites 1. When the fleet 33 is put into orbit, statistically it ensures regular observation (of the order of daily observation) of all the areas to be covered, by saturation effect. All the areas to be covered jointly form what is called the coverage area.

As an example, a satellite 1 according to the invention can record a 12 km wide band of terrain on the surface of the Earth with a resolution of one meter (12,000 detectors), during one third of its period of revolution. It can thus supply observation of 80 km² of ground surface per second, or about 2,500,000 km² per day, or 0.5% of the surface of the Earth. To ensure high probability of observation by day of any area of the surface of the Earth, apart from random meteorological events, 200 satellites 1 according to the invention, orbiting randomly, are enough. With a mass less than 5 kg for each satellite 1 the whole represents a total mass of the order of one tonne. Each satellite 1 can be located by the telemetry which it emits. The payload of each satellite 1 can be simply and easily protected, using reflecting films, from electromagnetic radiation which may damage electronic circuits and other components of the satellite. At an altitude of 5,000 km, such a satellite can offer a resolution of 10 m and a field of observation of 120 km. A single satellite can then capture 4% of the Earth per day, and 25 satellites can be enough statistically to give access daily to every point of the globe.

Without propulsion, the satellites 1 cannot maintain synchronism with the Sun in the long run. This is why it is preferable to place the satellites 1 according to the invention in inclined orbits. The satellites 1 can be placed in orbits at 60° or 65° to observe continental masses except Antarctica.

After being put into orbit, the satellite 1 receives remote control commands from the ground, and more precisely from a remote control/telemetry station on the ground of the celestial body 2. In a variant, this station can be arranged at any other point in space, provided that it is capable of emitting remote control signals to the antenna 26 of the satellite 1 or receiving signals from this antenna 26, via a radio link such as is traditionally used in remote control/telemetry links of satellites.

The satellite must be able to be the subject of several remote control functions.

The first function consists of orienting the row of detectors of the detecting component 17 perpendicularly to the trajectory of the satellite and to the trace of this trajectory on the ground of the celestial body 2. When a fault of perpendicularity of the detecting component 17 relative to this trajectory is detected on the ground, a command can be sent to initiate operation of the motor of the motorized orientation device, i.e. the counterrotation motor 50, to make the detecting device 7, and therefore the detecting component 17, pivot around the detection axis 16.

The second remote control function, if no telemetry is received from the satellite, consists of controlling the starting of microthrusters 39 which are fixed, for example, on the counterrotating part 22 to impart a force with a radial component to the receiving device 6. In fact, in this case it is possible that the satellite 1 is stabilized by gravity gradient in the opposite direction to a nominal aiming orientation, i.e. with the reflecting surface 36 oriented away from the celestial body 2. To make it return to an aiming orientation, it is enough to impart a rotational force around a transverse (i.e. approximately orthogonal to the longitudinal direction) axis to it, according to a predetermined value because of the device with microthrusters 39. It is possible either to dimension the corresponding force to cause rotation of the satellite 1 on itself with an amplitude corresponding exactly to a return to the nominal aiming orientation, or to repeat the use of the device with microthrusters 39 until a signal is received. Statistically, there is one chance in two that the satellite 1 is stabilized in a nominal aiming orientation. Several types of microthruster can be used, such as those described in the French patent FR-2 795 135.

A second embodiment provides for the use of the device to damp or amplify the oscillations of the satellite as described above, to amplify the oscillating movement of the satellite 1 until it is tipped.

A third embodiment provides for the combined use of the device to damp or amplify the oscillations of the satellite 1 and the microthrusters 39, to tip the satellite 1.

The third remote control function consists of adjusting the actuators 20, 11 collectively or individually, to adjust the lengths of the threadlike suspension lines 9, and/or to adjust the position of the detecting component using the motor 44 which is associated with the suspension device 35. This adjustment can be carried out until the image which the station receives is optimal.

In the case that the obtained information is digitized on board the satellite 1, e.g. using digitizing means of the electronic card 34, or in the case that information is captured digitally, e.g. with a CCD strip, the fourth remote command consists of being able to adjust the sampling frequency according to the altitude of the satellite 1 and as a function of its velocity of travel. In fact, this involves a clock frequency, i.e. a digital value which can easily be adjusted by command from the ground. This command is all the more important because the orbit 8 of the satellite 1 can be eccentric. In fact, the velocity of the satellite 1 relative to the ground is not constant in this case.

The fifth remote control function consists of triggering the device to damp or amplify the pitching or rolling oscillations so as to damp a pendular oscillation as described above.

The sixth remote control function may consist of sending a key to encrypt the telemetry signals which the satellite 1 sends back to the ground.

Finally, a remote control function must make it possible to stop the operation of the electronic card 34 permanently, at the end of the life of the satellite 1, to avoid polluting the radio frequency spectrum.

All these remote commands combined correspond to an extremely low flow of data to the satellites 1.

On the other hand, telemetry corresponds to a much greater flow of data. Data compression techniques such as the JPEG standard can be envisaged to minimize the necessary bandwidth.

The invention can be the subject of numerous variant embodiments, and various applications other than those described above.

In particular, the general geometry of the capture system 3 can be different from what is described above and shown in the figures (in the general form of a parachute). For example, there is nothing to prevent providing a structure which extends radially at the level of the receiving device 6 so that the threadlike suspension lines 9 can be arranged parallel to the axis 21 of the reflecting device in the deployed state. This structure, which can extend between the receiving device 6 and the free extremity of each threadlike suspension line 9, must nevertheless be transparent to electromagnetic radiation from the celestial body 2 toward the reflecting surface 36. For example, it can be a structure with spokes. Similarly, the various linking and/or motorizing mechanical devices (motors 49, 50, 44, suspension device 35, actuators, etc.) can be the subject of very numerous implementation variants.

Although it may increase the cost, of course there is nothing to prevent the satellite 1 according to the invention including an energy storage device such as a battery, and/or a device for on-board storage of information such as an electronic memory, and/or a locating device.

Additionally, it is possible to provide for equipping a satellite according to the invention with specialized reflecting surfaces (other than the reflecting surface 36 of the reflecting device 5) to protect those components of the satellite 1 which are sensitive to thermal radiation, such as the electronics of the detecting device 7 and the telemetry system.

It should be noted that a satellite 1 such as has been described can be the subject of industrial mass production, unlike known observation satellites.

Additionally, the general, characteristic dimensions given as examples above apply essentially to terrestrial observation in the visible range. The invention makes it possible to observe planets other than the Earth, and is applicable in particular to Martian observation.

The invention is also applicable in particular to passive or active observation in the microwave range. It should be noted that active observation necessitates emission of a pulse as for operation of radar. In such a case, it is necessary to equip the capture system with at least one emitter which is adapted to be able to generate an electromagnetic pulse belonging to the microwave range. The emitter is preferably placed in a location of the incidence plane, and oriented toward the reflecting surface 36 so that the pulse is reflected there in the direction of an area of the celestial body 2 to be observed. Preferably, a waveguide, called an active horn, can take the role of emitter of the pulse and receiver of the echo alternately.

In particular, for example, the capture system 3 of the satellite 1 can consist of an altimeter, rain radar, synthetic aperture radar (SAR) or other.

In practice, the rain radar can be implemented using a battery of active horns forming the detecting component. The active horns are arranged in the incidence plane in a row which is intended to extend on one side and the other of the detection axis 16, and to be placed perpendicularly to the velocity of the satellite. The echo which one of the two horns at the ends of the row receives can be analyzed periodically using a signal processing means of the electronic card 34 to determine its mean Doppler shift. This value makes it possible to determine the angle which the row of horns presents relative to the trajectory of the satellite 1 over the ground. The mean Doppler shift could thus be used, in combination with the counterrotation motor 50 and means of controlling the electronic card 34, to regulate automatically the angular position of the row of waveguides relative to the trajectory of the satellite 1 over the ground.

It is also possible to implement passive observation of areas of the celestial body 2 using a similar detecting component with passive horns, i.e. waveguides which do not emit pulses. This involves observing the radiation which emanates from the areas of the celestial body 2 in conformity with the techniques of passive microwave radiometry. For example, a satellite with such a detecting component can carry out measurements of the surface humidity of the celestial body. An active horn is preferably placed at the end of the row of the battery of waveguides to make it possible to calculate the mean Doppler shift as described above, so that the detecting component can be oriented.

The synthetic aperture radar is implemented in practice using a detecting component with a rigid structure, on which an active horn is placed. The rigid structure is suitable for placing the active horn approximately in the incidence plane and shifted relative to the detection axis 16 when the reflecting device 5 and receiving device 6 are in the functioning relative position. This observation position of the active horn makes it possible to observe the surface of the celestial body 2 at an angle. The electronic card 34 is equipped with suitable means of processing the signal to be able to implement the synthetic aperture and the compression of pulses in conformity with the operation of synthetic aperture radar.

In practice, an altimeter can be implemented using a detecting component with a single active horn which is placed in the incidence plane, approximately at the focal distance of the reflecting surface 36. The receiving device 6 can be greatly simplified in such a case.

In fact it is no longer necessary to orient the detecting component relative to the trajectory of the satellite over the ground. Thus the motorized orientation device, the counterrotating part 22 and the suspension device 35 as described above are no longer useful. They can therefore be omitted from the satellite according to the invention. A rigid structure, which supports the detecting component, the electronic card 34 and the telemetry antenna, can be connected directly to the threadlike suspension lines 9, replacing the bush 40 and bracket 31.

It is also possible to combine several of the above configurations, to implement a satellite according to the invention with a multifunctional capture system. It would thus be possible to use the same satellite 1 according to the invention as an altimeter, SAR, rain radar etc.

The capture system 3 according to the invention can also be adapted to be able to carry out infrared cartography of a celestial body such as the Earth, by using microbolometers as detectors.

1-36. (canceled)

37. An observation satellite which is intended to be placed in orbit around a celestial body, and which includes a suitable capture system to capture information which is received in the form of electromagnetic radiation, the capture system comprising:
a receiving device including a suitable detecting device to capture the said information,
a device to reflect the said received electromagnetic radiation, comprising at least one reflecting surface, and
a linking mechanical system which moors the reflecting device and receiving device to each other, this capture system being suitable to be able to capture the said information when the receiving device and reflecting device are placed relative to each other in a functioning relative position in which the detecting device receives all or part of the said electromagnetic radiation which is reflected by the reflecting device, and captures the corresponding information, wherein the capture system is suitable, by its geometry and mass distribution, to orient itself of its own accord by gravity gradient according to an aiming orientation, in which when the receiving device and reflecting device are in a functioning relative position, the reflecting device is oriented toward the celestial body to be able to receive the electromagnetic radiation which originates in an area of the celestial body, called the aimed-at area, the capture system being capable of capturing information which is to be captured and is transmitted by this electromagnetic radiation.

38. A satellite as claimed in claim 37, wherein the linking mechanical system is suitable for placing the reflecting device and receiving device relative to each other in at least two distinct configurations, corresponding respectively to two states of the capture system:
one state called deployed, in which the reflecting device and receiving device are stabilized in the functioning relative position under the effect of the gravity gradient, and
one state called folded, in which the receiving device and reflecting device are close to each other, and the capture system is more compact than in the deployed state, and therefore suitable for being loaded into a launcher and/or for storage.

39. A satellite as claimed in claim 38, wherein the linking mechanical system is of a type which is flexible and inelastic under flexion, and is suitable for stretching under the effect of the gravity gradient when the satellite is placed in orbit, until it reaches an equilibrium configuration in which the capture device is stabilized in the deployed state.

40. A satellite as claimed in claim 37, wherein the linking mechanical system comprises at least three threadlike suspension lines which are rigid under traction and flexible and inelastic under flexion, and each having two extremities, of which the first extremity is fixed to the reflecting device and the second extremity is fixed to the receiving device, the said suspension lines being each fixed at distinct places of the reflecting device and receiving device, in such a way that:
the attitudes of the receiving device and reflecting device can stabilize relative to each other under the effect of the gravity gradient, when the capture system is in the deployed state, the threadlike suspension lines do not intercept the electromagnetic radiation which comes from the reflecting surface(s) and advances toward the detecting device.

41. A satellite as claimed in claim 40, wherein the threadlike suspension lines consist of one or more materials which are chosen so that the lengths of the threadlike suspension lines remain approximately constant despite the thermal fluctuations to which they may be subjected once the satellite is placed in orbit.

42. A satellite as claimed in claim 40, wherein the threadlike suspension lines consist entirely or partly of one or more materials which are suitable for absorbing at least the electromagnetic radiation belonging to the spectral range to be observed, so that these suspension lines do not generate any interfering reflection on the detecting device.

43. A satellite as claimed in claim 40, wherein the threadlike suspension lines are chains.

44. A satellite as claimed in claim 40, wherein the linking mechanical system comprises motorized means of adjusting the length of at least one of the threadlike suspension lines.

45. A satellite as claimed in claim 44, wherein the motorized means of adjustment include at least one piezoelectric actuator.

46. A satellite as claimed in claim 37, wherein it comprises a plurality of masks which are jointly suitable, when the reflecting device and receiving device are in the functioning relative position, for masking the detecting device against the direct incidence of electromagnetic radiation belonging to the spectral range to be observed, and originating in sources which are external to the internal volume of the capture system, which is geometrically circumscribed by the mask(s), the linking mechanical system, the reflecting device and the receiving device.

47. A satellite as claimed in claim 46, wherein the reflecting device includes at least one peripheral mask, called gutter, which is adapted to extend around the periphery of the reflecting surface(s).

48. A satellite as claimed in claim 46, wherein the receiving device includes at least one mask, called blinker, which extends as a whole toward the reflecting device when the reflecting device and receiving device are in the functioning relative position.

49. A satellite as claimed in claim 37, wherein the detecting device includes at least one detecting component comprising at least one detector which is chosen from charge transfer detectors, waveguides, microbolometers.

50. A satellite as claimed in claim 49, wherein:
at least one reflecting surface is concave and has symmetry of revolution around an axis, called the axis of the reflecting device, and suitable for observing an area of the celestial body centered on the axis of the reflecting device, and
the detecting component is at least approximately placed in the axis of the reflecting device when the reflecting device and receiving device are in the functioning relative position.

51. A satellite as claimed in claim 50, wherein, the reflecting surface being in the form of a paraboloid of revolution, the ratio between the focal distance and the diameter of the reflecting surface is greater than 5.

52. A satellite as claimed in claim 49, wherein the capture system includes at least one filter which blocks thermal infrared radiation, and is placed to protect the detecting component from thermal infrared radiation from the reflecting device.

53. A satellite as claimed in claim 37, wherein it includes an electrical power supply with photovoltaic cells.

54. A satellite as claimed in claim 53, wherein photovoltaic cells are arranged on at least one surface of the reflecting device, opposite the reflecting surface(s).

55. A satellite as claimed in claim 37, wherein it includes an electrical power supply with photovoltaic cells, wherein photovoltaic cells are arranged on at least one surface of the reflecting device, opposite the reflecting surface(s), and wherein it includes at least one flexible conducting power supply cord of a length greater than that of the linking mechanical system in the deployed state, and electrically connecting the photovoltaic cells which are arranged on the reflecting device to the receiving device.

56. A satellite as claimed in claim 37, wherein it includes an electrical power supply with photovoltaic cells, wherein photovoltaic cells are arranged on at least one surface of the reflecting device, opposite the reflecting surface(s), wherein it includes at least one flexible conducting power supply cord of a length greater than that of the linking mechanical system in the deployed state, and electrically connecting the photovoltaic cells which are arranged on the reflecting device to the receiving device, and wherein:
the receiving device includes a bracket on which the detecting device is mounted so that it rotates around an axis, called the detection axis, and
the detecting device includes a motorized device to orient the detecting device around the detection axis.

57. A satellite as claimed in claim 56, wherein the receiving device includes a device for electromagnetic and/or mechanical suspension of the detecting device relative to the bracket of the receiving device, with negligible friction.

58. A satellite as claimed in claim 37, wherein the capture system includes a device, called the damping or amplifying device, to make it possible to damp or amplify the pitching and rolling oscillations of the satellite when the reflecting device and receiving device are in the functioning relative position.

59. A satellite as claimed in claim 58, wherein the damping or amplifying device includes a suitable motor to lift or lower at least one mass along the detection axis.

60. A satellite as claimed in claim 37, wherein it includes a suitable telemetry device to transmit captured information to a reception station at a distance from the satellite.

61. A satellite as claimed in claim 37, wherein the capture device includes a device to fix the receiving device temporarily within a blind area of the reflecting surface, making it possible to keep the capture system in the folded state.

62. A satellite as claimed in claim 37, wherein the capture system includes suitable means to make it pivot around a transverse axis of the capture system when the reflecting device and receiving device are in the functioning relative position.

63. A satellite as claimed in claim 37, wherein the reflecting device is adapted so that the reflecting surface reaches a functional geometric equilibrium in less than a semi-period of revolution around the celestial body when the reflecting device is subjected to thermal stress by passing from a segment of orbit in which a source of thermal radiation is eclipsed to a segment of orbit which is exposed to the said source.

64. A satellite as claimed in claim 37, wherein its mass is less than 10 kilograms.

65. A method of observing a celestial body, in which:
at least one satellite is placed in orbit around the celestial body, said satellite including a suitable capture system to capture information which is received in the form of electromagnetic radiation, the capture system comprising:
a receiving device including a suitable detecting device to capture the said information,
a device to reflect the said received electromagnetic radiation, comprising at least one reflecting surface, and
a linking mechanical system which moors the reflecting device and receiving device to each other, this capture system being suitable to be able to capture the said information when the receiving device and reflecting device are placed relative to each other in a functioning relative position in which the detecting device receives all or part of the said electromagnetic radiation which is reflected by the reflecting device, and captures the corresponding information, and wherein the capture system is suitable, by its geometry and mass distribution, to orient itself of its own accord by gravity gradient according to an aiming orientation, in which when the receiving device and reflecting device are in a functioning relative position, the reflecting device is oriented toward the celestial body to be able to receive the electromagnetic radiation which originates in an area of the celestial body, called the aimed-at area, the capture system being capable of capturing information which is to be captured and is transmitted by this electromagnetic radiation, each satellite is allowed to orient itself by gravity gradient.

66. A method as claimed in claim 65, wherein a fleet of several satellites is placed in at least one orbit.

67. A method as claimed in claim 65, wherein each satellite is placed in a non-geostationary orbit, and a suitable number of satellites is used to make it possible statistically to capture observation information daily on all portions of at least one area of coverage of the celestial body, by saturation.

68. A method as claimed in claim 65, wherein each satellite is allowed to describe a natural orbital trajectory without active correction of this orbital trajectory.

69. A method as claimed in claim 65, wherein at least one launcher is used, and multiple satellites of a satellite fleet are grouped in it to be placed in orbit around the celestial body.

70. A method as claimed in claim 69, wherein:
the reflecting devices of the said satellites are fitted into each other in a stack on a platform of a launcher, and
the receiving devices of the said satellites are placed on the platform around the stack, each of them being placed on a suitable ejecting device to propel it outside the launcher when it is put into orbit.

71. A fleet of observation satellites placed in at least one orbit around a celestial body, each satellite including a suitable capture system to capture information which is received in the form of electromagnetic radiation, the capture system comprising:
a receiving device including a suitable detecting device to capture the said information,
a device to reflect the said received electromagnetic radiation, comprising at least one reflecting surface, and
a linking mechanical system which moors the reflecting device and receiving device to each other, this capture system being suitable to be able to capture the said information when the receiving device and reflecting device are placed relative to each other in a functioning relative position in which the detecting device receives all or part of the said electromagnetic radiation which is reflected by the reflecting device, and captures the corresponding information, and wherein the capture system is suitable, by its geometry and mass distribution, to orient itself of its own accord by gravity gradient according to an aiming orientation, in which when the receiving device and reflecting device are in a functioning relative position, the reflecting device is oriented toward the celestial body to be able to receive the electromagnetic radiation which originates in an area of the celestial body, called the aimed-at area, the capture system being capable of capturing information which is to be captured and is transmitted by this electromagnetic radiation.

72. A fleet as claimed in claim 71, wherein the satellites are placed in at least one non-geostationary orbit, and the fleet comprises a suitable number of satellites to make it possible statistically to capture observation information daily on all portions of at least one area of coverage of the celestial body, by saturation.
